(19) United States
(12) Patent Application Publication
(10) Pub. No.: US 2024/0356568 A1
(43) Pub. Date: Oct. 24, 2024

(54) VIRTUALIZED RADIO ACCESS POINT, VRAP, AND METHOD OF OPERATING THE SAME

(71) Applicant: NEC Laboratories Europe GmbH, Heidelberg (DE)

(72) Inventors: Andres GARCIA SAAVEDRA, Heidelberg (DE); Xavier COSTA-PEREZ, Heidelberg (DE)

(21) Appl. No.: 18/574,818

(22) PCT Filed: Jun. 30, 2021
(86) PCT No.: PCT/EP2021/068065

§ 371 Date: Dec. 28, 2023

(51) Int. Cl. H03M 13/00; H03M 13/11; H03M 13/29; H03M 13/35

(52) U.S. Cl. CPC H03M 13/6306; H03M 13/1128; H03M 13/2975; H03M 13/353

(57) ABSTRACT

A method of operating a virtualized radio access point (vRAP) is provided. Transport blocks (TBs) are encoded/decoded by using iterative codes that exchange extrinsic information in each iteration. The exchanged extrinsic information is exploited to infer information about decodability of the data of the TBs.

### CROSS REFERENCE TO RELATED APPLICATIONS

This application is a U.S. National Phase application under 35 U.S.C. § 371 of International Application No. PCT/EP2021/068065, filed on Jun. 30, 2021. The International Application was published in English on Jan. 5, 2023 as WO 2023/274528 A1 under PCT Article 21 (2).

### FIELD

The present invention relates to a virtualized radio access point, vRAP, and to a method of operating the same.

### BACKGROUND

The virtualization of radio access networks (RANs), based hitherto on monolithic appliances over application-specific integrated circuits (ASICs), will become the spearhead of next-generation mobile systems beyond 5G and 6G. Initiatives such as the carrier-led O-RAN alliance or Rakuten's greenfield deployment in Japan have spurred the market—and so the research community—to find novel solutions that import the flexibility and cost-efficiency of network function virtualization (NFV) into the very far edge of mobile networks.

Compared to purpose-built RAN hardware, virtualized RANs (vRANs) pose several advantages, such as:
1. Leverage off-the-shelf platforms, which are more cost-efficient over the long-term due to economies of scale;
2. Harmonize the ecosystem, which helps reduce costs;
3. Leverage tools such as agile, DevOps or CI/CD, which shorten development cycles; and
4. Enable seamless integration of cloud technologies, which lowers barriers for competition and innovation.

FIG. 1 shows the architecture of a vRAN 100 according to prior art. More specifically, FIG. 1 schematically illustrates the structure of a base station (BS), i.e. radio access point (RAP) 110 in a 5G RAN architecture. Regardless of the different terminology used for the radio access point—eNodeB (eNB) in 4G LTE or gNodeB (gNB) in 5G—the term RAP, or vRAP for its virtualized counterpart, will be used in the present disclosure as an abstraction. As depicted in FIG. 1, 5G splits each RAP 110 into a central unit (CU) 120, hosting the highest layer of the stack; a distributed unit (DU) 130, hosting the physical layer (PHY) 132 and the MAC (Media Access Control) scheduler 134; and a radio unit (RU) 140, hosting basic radio functions such as amplification or sampling.

As can be obtained from FIG. 1, vRANs 100 shall rely on cloud platforms, comprised of pools of shared computing resources 150 (mostly CPUs, but also GPUs, FPGAs and other hardware accelerators brokered by an abstraction layer 160, for reference, see, e.g. bbdev (https://doc.dpdk.org/guides/prog_guide/bbdev.html)), to host virtualized functions such as the PHY.

However, while CUs are amenable to virtualization in regional clouds, virtualized DUs (vDUs)—specifically the vPHY therein—require fast and predictable computation in edge clouds. Clouds provide a harsh environment for DUs because they trade off the predictability supplied by dedicated platforms for higher flexibility and cost-efficiency. Indeed, research has shown that resource contention in cloud infrastructure, even when placing virtual functions on separate cores, may lead to up to 40% of performance degradation compared to dedicated platforms—the so-called noisy neighbor problem.

This is certainly an issue for traditional network functions such as virtual switches, firewalls, VPNs, or even CUs, which only suffer a performance degradation that is proportional to the computing fluctuations caused by resource contention. For contemporary 4G/5G PHY pipelines, however, such fluctuations are simply catastrophic. Consequently, a main challenge for DU virtualization is to design a virtual PHY processor that preserves carrier-grade performance in cloud platforms at the edge.

Recently, E-HARQ (Early Hybrid Automated Repeat Request) is receiving attention in the context of low-latency communications. The approach is usually to design appropriate stopping criteria for the iterative algorithms employed by turbo decoders (as disclosed, e.g., in P. Salija and B. Yamuna: “An efficient early iteration termination for turbo decoder”, in Journal of Telecommunications and Information Technology, 2016, the entire contents of which is hereby incorporated by reference herein) or LDPC decoders (as disclosed, e.g., in Jiangpeng Li et al.: “Memory efficient layered decoder design with early termination for LDPC codes”, in 2011 IEEE International Symposium of Circuits and Systems (ISCAS), IEEE, 2697-2700, the entire contents of which is hereby incorporated by reference herein), or to predict the decodability of the data to send HARQ feedback early (as disclosed, e.g., in Nils Strodthoff et al.: “Enhanced machine learning techniques for early HARQ feedback prediction”, in 5G.IEEE Journal on Selected Areas in Communications 37, 11 (2019), 2573-2587, the entire contents of which is hereby incorporated by reference herein). However, these approaches merely aim at reducing delay and have therefore a limited efficiency only.

### SUMMARY

In an embodiment, the present disclosure provides a method of operating a virtualized radio access point (vRAP), the method comprising: encoding/decoding transport blocks (TBs) by using iterative codes that exchange extrinsic information in each iteration; and exploiting the exchanged extrinsic information to infer information about decodability of the data of the TBs.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 is a schematic view illustrating the concept of virtualized RAN architecture according to prior art;

FIG. 2 is a schematic view illustrating pipeline parallelization in a conventional baseline digital signal processor (DSP) according to prior art;

FIG. 3 is a diagram showing the decoding time of one transport block in a CPU core;

FIG. 4 is a schematic view illustrating the basic concept of a multi-thread PHY pipeline according to a previous solution;

FIG. 5 is a schematic view illustrating the structure of a transport block (TB) as implemented in 4G/5G;

FIG. 6 is a schematic view illustrating an exemplary architecture of a turbo encoder (a) and a turbo decoder (b);

FIG. 7 is a diagram exemplarily illustrating experimental results of the mean extrinsic magnitude for each iteration of a turbo decoder;

FIG. 8 is a diagram schematically illustrating the concept of a HARQ prediction approach in accordance with an embodiment of the present invention;

FIG. 9 is a diagram schematically illustrating the scenario with a decodable transport block in accordance with an embodiment of the present invention;

FIG. 10 is a diagram schematically illustrating the scenario with an undecodable transport block in accordance with an embodiment of the present invention; and

FIG. 11 is a diagram schematically illustrating the scenario with an inconclusive decodability of a transport block in accordance with an embodiment of the present invention.

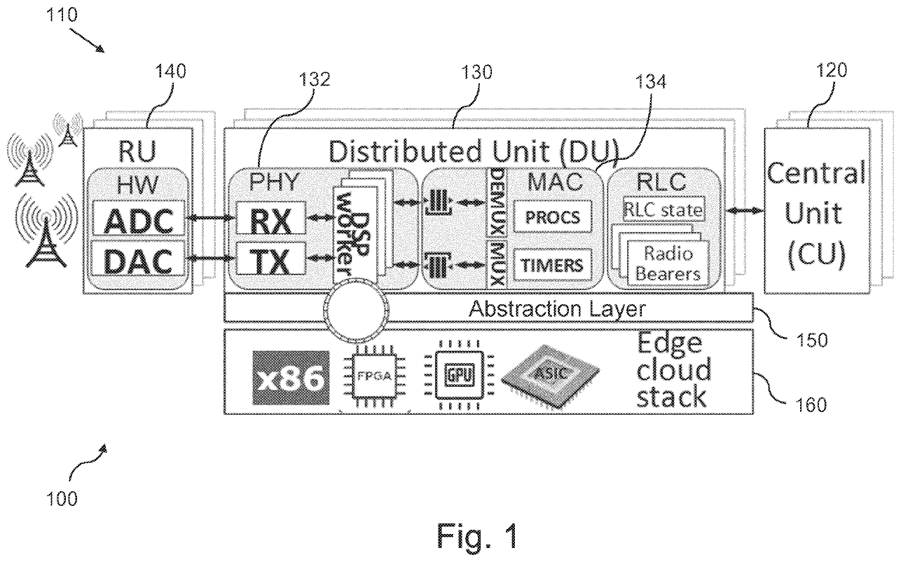

### DETAILED DESCRIPTION

In accordance with an embodiment, the present invention improves and further develops a virtualized radio access point, vRAP, and a method of operating the same in such a way that high-performing DU virtualization is enabled in order to maximize performance in cloud-based virtualized RANs.

In accordance with another embodiment, the present invention provides a method of operating a virtualized radio access point, vRAP, the method comprising: encoding/decoding transport blocks, TBs, by using iterative codes that exchange extrinsic information in each iteration; and exploiting the exchanged extrinsic information to infer information about the decodability of the data of the TBs.

Furthermore, in accordance with another embodiment, the present invention provides a virtualized radio access point, vRAP, comprising an encoder/decoder configured to encode/decode transport blocks, TBs, by using iterative codes that exchange extrinsic information in each iteration; and a digital signal processor, DSP, pipeline configured to infer information about the decodability of the data of the TBs by exploiting the exchanged extrinsic information.

According to the invention it has first been recognized that common cloud platforms, typically comprised of pools of shared computing resources (mostly CPUs, but also hardware accelerators brokered by an abstraction layer), provide a harsh environment for 4G/5G (and possibly beyond) virtualized distributed units (vDUs) because they trade off the predictability supplied by dedicated platforms for higher flexibility and cost-efficiency. Therefore, embodiments of the present invention aim at improving the efficiency of virtualized PHYs when data processing tasks cannot be finished in time due to e.g., cloud computing fluctuations. As a solution, embodiments of the present invention built upon two main techniques: (i) Hybrid Automated Repeat Request (HARQ) prediction, and (ii) congestion control, aims at increasing the performance of vDUs running on cloud platforms. Specifically, embodiments of the invention propose a HARQ prediction mechanism that 1) avoids forcing users to retransmit data that would be decodable if they had more computing budget time and 2) provides information to the MAC scheduler of the vRAP to control the rate of data to the availability of computing resources in the edge cloud. As a result, the efficiency of virtualized base stations (O-RAN) is increased.

It should be noted that, while the above mentioned E-HARQ related approaches just try to reduce delay, embodiment of the present invention differ from these approaches in that extrinsic information from the decoders is exploited to infer the decodability of data to provide extra computing time budget to data processing workers and possibly adapt the rate of data to the computing capacity of the system.

According to an embodiment of the present invention, the codes used for encoding/decoding transport blocks, TBs (or the code blocks, CBs, of a TB, respectively) may include turbo codes and/or LDPC (low-density parity-check) codes. Both types of encoder/decoder may employ an iterative belief propagation algorithms, which may be exploited to infer the future decodability of each TB (or CB, respectively).

According to an embodiment, the encoder/decoder may be a turbo encoder/decoder configured to operate based on two interleaved convolutional codes. More specifically, the turbo decoder may be configured to execute a belief propagation algorithm that is implemented by two convolutional decoders that exchange extrinsic log-likelihood ratios, LLRs, iteratively. In this regard, it may be provided that the LLRs represent a reliability information computed for a received sequence of systematic bits and parity bits generated by the corresponding turbo encoder.

According to an embodiment, inferring information about the decodability of the data of the TBs includes determining, based on an analysis of the exchanged extrinsic information, a decodability status of the data as either ‘decodable’, ‘undecodable’ or ‘unknown’.

According to an embodiment, processing extrinsic information for inferring information about the decodability of the data of the TBs may be performed when a deadline for computing signals to send feedback to the respective users expires.

According to an embodiment, it may be provided that the magnitude of the extrinsic information after the last decoding iteration is determined. Based thereupon, it can be inferred that the respective data are decodable if the determined magnitude exceeds a first configurable threshold. Alternatively or additionally, it may be provided that the trend of the magnitude of the extrinsic information over the decoding iterations is determined. Based thereupon, it can be inferred that the respective data are decodable if the determined trend exceeds a second configurable threshold. These tasks can be performed by appropriately built classifiers.

According to an embodiment, it may be provided that, if user data are determined to be decodable, a signal is computed to acknowledge its successful reception to the transmitter (e.g. by sending an ACK to the respective user), while the decoder may continue processing the user data in parallel.

According to an embodiment, it may be provided that, if user data are determined to be undecodable or if the inferred information about the decodability do not permit to determine whether user data are decodable or not, decoding the data is stopped and the signals to request the user to retransmit the data are computed.

According to an embodiment, it may be provided that, if user data are determined to be decodable, the amount of data the MAC scheduler is allowed to allocate to users is increased. Alternatively or additionally, it may be provided that, if user data are determined to be undecodable or if the inferred information about the decodability do not permit to determine whether user data are decodable or not, the amount of data the MAC scheduler is allowed to allocate to users is decreased.

According to an embodiment, it may be provided that the inferred information about the decodability of data is used to adapt the rate at which uplink data is scheduled to the availability of the vRAP's computing capacity. For instance, this may be accomplished by using additive-increase/multiplicative-decrease (AIMD) algorithms.

According to embodiments, the DSP pipeline of the vRAP may be configured to process 4G LTE or 5G NR workloads in sub 6 GHz frequency bands that are virtualized in general-purpose CPU clouds.

There are several ways how to design and further develop the teaching of the present invention in an advantageous way. To this end, it is to be referred to the dependent claims on the one hand and to the following explanation of preferred embodiments of the invention by way of example, illustrated by the figure on the other hand. In connection with the explanation of the preferred embodiments of the invention by the aid of the figure, generally preferred embodiments and further developments of the teaching will be explained.

4G LTE and 5G NR (NR) PHYs have a number of similarities. Therefore, before describing embodiments of the invention in detail, first, the most important aspects of 4G LTE and 5G New Radio that are relevant for at least some embodiments of the invention and that will probably ease their understanding, are introduced and the key insufficiencies of a legacy pipeline will be outlined. A more detailed description of the respective technology can be obtained from Erik Dahlman, Stefan Parkvall, and Johan Skold. 2018.5G NR: “The next generation wireless access technology”, Academic Press and references therein.

5G NR adopts orthogonal frequency division multiplexing access (OFDMA) with cyclic prefix (CP) for both downlink (DL) and uplink (UL) transmissions, which enables fine-grained scheduling and multiple-input multiple-output (MIMO) techniques. While LTE also adopts OFDM in the DL, it relies on single-carrier FDMA (SC-FDMA) for the UL, a linearly precoded flavor of OFDMA that reduces peak-to-average power ratio in mobile terminals. The numerology differs between LTE and NR. In both cases, a subframe (SF) consists of a transmission time interval (TTI) that lasts 1 ms, and a frame aggregates 10 SFs. LTE has a fixed numerology with inter-subcarrier spacing equal to 15 kHz, and a SF being composed of 2 slots, each with 7 (with normal CP) or 6 (with extended CP) OFDM symbols. In contrast, NR allows different numerologies, with tunable subcarrier spacing between 15 and 240 KHz. To support this, NR divides each SF into one or more slots, each with 14 (with normal CP) or 12 (with extended CP) OFDM symbols. Finally, LTE supports different bandwidth configurations, up to 20 MHz, whereas NR allows up to 100 MHz in sub-6 GHz spectrum; and both support carrier aggregation with up to 5 (LTE) or 16 (NR) carriers.

The PHY is organized into channels, which are multiplexed in time and frequency. Although LTE and NR use mildly different channel formats and time/spectrum allocations, they are conceptually very similar. The unit of transmission is the transport block (TB). Within each TTI, PDSCH (Physical DL Shared Channel) and/or PUSCH (Physical UL Shared Channel) carries one TB per user (or two, in case of spatial multiplexing with more than four layers in DL) as indicated by PDCCH's (Physical DL Control Channel) Downlink Control Information (DCI), which carries DL and UL resource scheduling information. The size of the TB is variable and depends on the modulation and coding scheme (MCS) used for transmission, which in turn depends on the signal quality, and of course on the state of data buffers. Hybrid automatic repeat request (HARQ), combining forward error correction and ARQ, is used for error control. To this end, explicit feedback is received from the users in UL Control Information (UCI) messages carried by PUSCH or PUCCH (Physical UL Control Channel), and TBs are encoded with low-density parity-check codes (NR) or turbo codes (LTE).

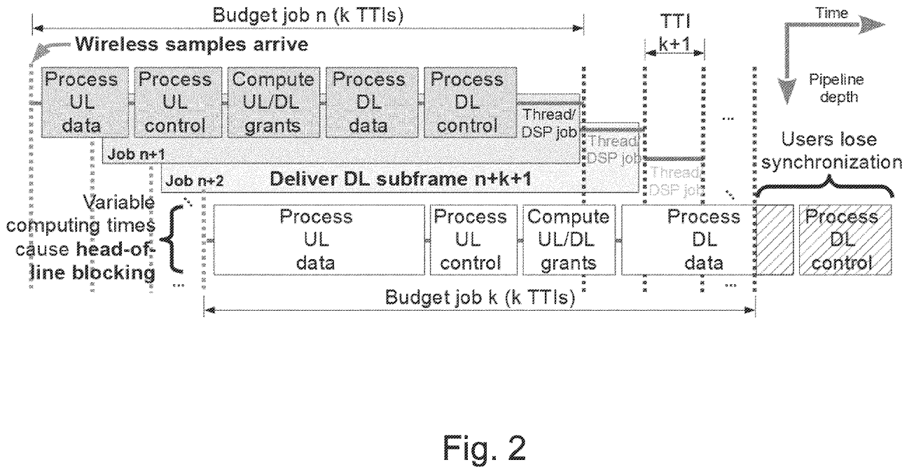

FIG. 2 illustrates the operation of a digital signal processor (DSP) that is commonly used to implement a 4G/5G PHY. Every transmission time interval (TTI), which is usually 1 ms in 4G/5G, a DSP worker initiates a job comprised of a pipeline of tasks, including: (i) processing an uplink (UL) subframe, (ii) scheduling UL and downlink (DL) grants, and (iii) compiling a DL subframe.

As already mentioned before, cellular systems implement a Hybrid Automated Repeat Request (HARQ) mechanism, which mixes forward error correction (FEC) coding with explicit ARQ feedback encoded into ACK (acknowledgement) or NACK (not acknowledgement) signals such that the user can retransmit undecodable data (due to bad channel conditions, for instance) or transmit new data instead.

The above pipeline of tasks has to be processed sequentially because of the dependency among them: In order to compile a DL subframe, UL and DL grants have to be computed because the signaling required to inform the users of UL and DL scheduling decisions is carried by the DL subframe. Moreover, in order to compute DL and UL grants, UL data processing tasks may be completed because UL grants depend on the decodability of UL data. For instance, if UL data cannot be decoded due to bad channel conditions, appropriate grants to schedule re-transmissions and a non-acknowledgement signal (NACK) have to be computed. Conversely, if UL data has been successfully decoded, an acknowledgement (ACK) has to be mapped into the DL subframe.

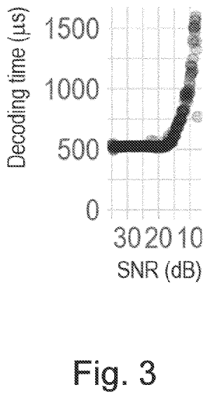

In addition, these are compute-intensive tasks and hence processing a job within 1 ms is challenging. For instance, FIG. 3 depicts the time it takes for a general-purpose CPU to decode a transport block of data from one user-just one out of many operations when processing an UL subframe-encoded with a mild modulation and coding scheme in a 20-MHz channel, and enduring different signal-to-noise-ratio (SNR) settings. However, processing a DSP job every TTI (e.g. every 1 ms) is vital to preserve synchronization and process control information. To give workers some slack, pipeline parallelization is commonly used, that is, a pool of workers processes multiple jobs in parallel as shown in FIG. 2. In this way, with a pool of k workers, each job n gets a computing budget of roughly k TTIs to process UL subframe n (corresponding to the nth TTI) and compile DL subframe n+k+1 (carrying DL signals during the (n+k+1) th TTI). Albeit this approach is the basis for most of the work conducted to date, it is certainly not sufficient for carrier-grade cloud-based vDUs.

One important problem is the fact that processing UL data is time-consuming (see FIG. 3) and hence causes head-of-line blocking, as illustrated at the bottom of FIG. 2, which compromises the delivery of DL grants in addition to causing synchronization and control plane issues. Moreover, the amount of computing time required by this task is also context-dependent, that is, it varies depending on the channel quality (and hence on the mobility of the users and other channel dynamics), the network load dynamics, and on cloud computing fluctuations due to resource contention when multiple vDU instances share the platform.

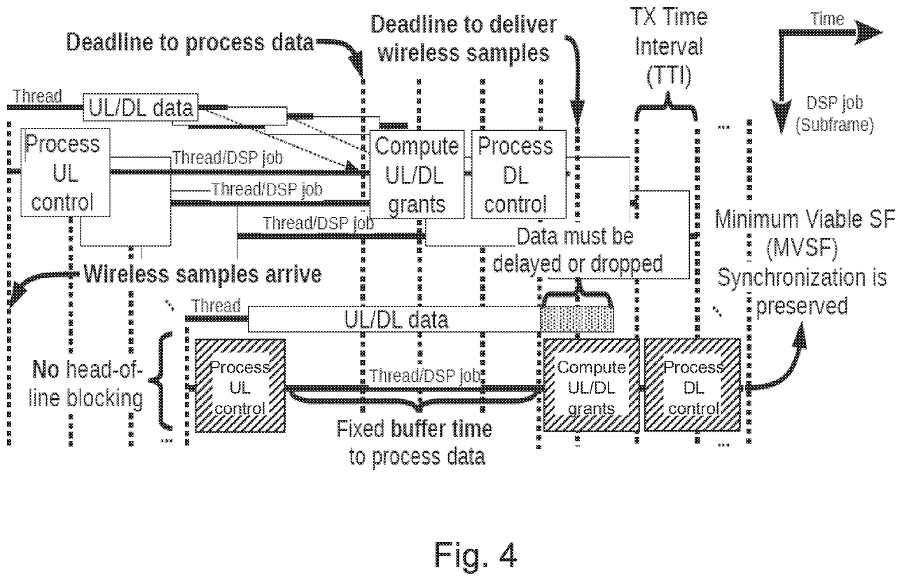

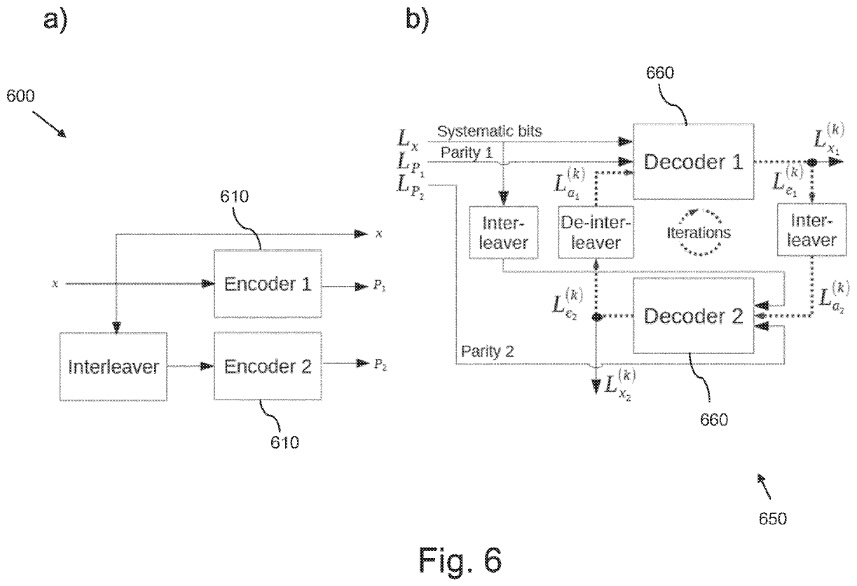

One solution to the aforementioned head-of-line blocking problem is to allocate a fixed time budget to uplink data processing tasks (PUSCH processing) in order to make sure that head-of-line blocking does not incur into violating the whole job's budget. An example of an approach that implements this solution is described in the applicant's previous application PCT/EP2020/083054 (not yet published), which decouples data processing tasks such as UL data processing tasks in parallel threads with a fixed time budget. If, upon exhausting this budget, the task is unfinished, it is discarded and the user is requested to retransmit its data. This is illustrated in the bottom part of FIG. 4 (which corresponds to FIG. 6 of the above mentioned previous application).

However, when the timer on data processing tasks expire (such as in case of the job depicted with a hatched area at the bottom of FIG. 4), data has to be discarded because it has not been yet decoded satisfactorily, feedback may be sent to the users and UL/DL grants have to be computed accordingly. Embodiments of the present invention aim at improving the efficiency of virtualized PHYs when data processing tasks cannot be finished in time due to e.g., cloud computing fluctuations (such as in case of the job depicted with a hatched at the bottom of FIG. 4). Specifically, embodiments of the invention provide a solution that proposes a HARQ prediction mechanism that 1) avoids forcing users to retransmit data that would be decodable if they had more computing budget time and/or 2) provides information to the MAC scheduler to control the rate of data to the availability of computing resources in the edge cloud.

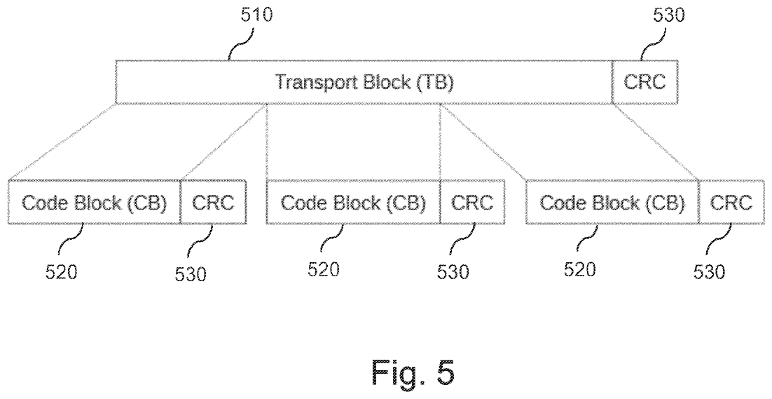

Each DSP job carries a number of transport blocks (TBs) 510, usually one per user, which carry user data. To encode/decode TBs in 4G/5G, each TB (usually 1 ms) is divided into multiple equal size code blocks (CBs) 520 of up to 8448 bits. Both the TB and each code block have a 16-bit or 32-bit cyclic redundancy check (CRC) 530 attached for error detection, as shown in FIG. 5.

4G/5G encode/decode CBs using turbo codes or LDPC codes, which are capable of achieving close-to-Shannon capacity and are amenable to efficient implementation. On the one hand, a turbo decoder consists of two interleaved concatenated convolutional codes, which exchange extrinsic information, and a trellis soft-decision algorithm that run iteratively. On the other hand, LDPC codes are linear block codes with sparse parity check matrices represented by a bipartite graph, which are decoded with a soft message passing algorithm. They have fundamental similarities, among which the most relevant is that both approaches employ an iterative belief propagation algorithm. Embodiments of the present invention exploit this iterative belief propagation algorithm to infer the future decodability of each TB. However, before describing embodiments of the present invention in more detail, in the following a brief overview of turbocoding is provided to introduce the concept of extrinsic information that is leveraged for decodability prediction according to embodiments of the invention.

As an example, FIG. 6 illustrates the architecture of a turbo encoder (FIG. 6a) and a turbo decoder (FIG. 6b). A turbo encoder 600 consists of two convolutional encoders 610 (Encoder 1 and Encoder 2). CBs are encoded/decoded one by one. For every CB, its constituent bits \vec{x} are fed into the turbo encoder 600. The output consists of a sequence of systematic bits x and a sequence of parity bits. The output of Encoder 1 generates a sequence of parity bits \vec{P₁}, and Encoder 2 generates a second sequence of parity bits \vec{P₂}, using an interleaved version of \vec{x}, i.e., \tilde{x}.

The receiver receives a possibly distorted version of the systematic bits and parity bits. A soft-output detector computes the reliability information as log-likelihood ratios (LLR) for the received sequence of systematic bits \vec{Lₓ} and parity bits \vec{L_{P}_{ᵢ}}, for i={1,2}. The sign of an LLR indicates the bit that is inferred, and its magnitude indicates the certainty of such inference. The turbo decoder's 650 belief propagation algorithm is implemented by two decoders (Decoder 1 and Decoder 2) 660 that exchange extrinsic LLRs \vec{Lₑ_{ₜ}}^{(k)} iteratively, where k={1, 2, . . . } indexes each full iteration. To this end, every iteration k, decoder i uses a maximum a-posteriori (MAP) algorithm to compute a-posteriori LLRs \vec{Lₓ_{ₜ}}^{(k)} based on the systematic LLRs \vec{Lₓ} (in case of i=1) or {right arrow over (L_{\tilde{x}})} (i.e., interleaved, in case of i=2), on the respective parity LLRs \vec{L_{P}_{ₜ}} and on the so-called a-priori LLRs \vec{Lₐ_{ₜ}}^{(k)}. Initially, \vec{Lₐ_{₁}}⁽¹⁾=0. In subsequent half-iterations, each decoder 660 computes extrinsic LLRs as

$${\vec{{L}_{{e}_{ι}}}}^{( k )} = {\vec{{L}_{{x}_{ι}}}}^{( k )} - \vec{{L}_{x}} - {\vec{{L}_{{a}_{m}}}}^{( k )} ,$$

$$∀ i \neq m ϵ \{ 1 , 2 \}$$

That is, as depicted in FIG. 6b, \vec{Lₐ_{₁}}^{(k)} is a deinterleaved version of \vec{Lₑ_{₁}}^{(k)}, and \vec{Lₐ_{₂}}^{(k)} is an interleaved version of \vec{Lₑ_{₂}}^{(k)}. At each full iteration k, CRC validation is used as a stopping criterion.

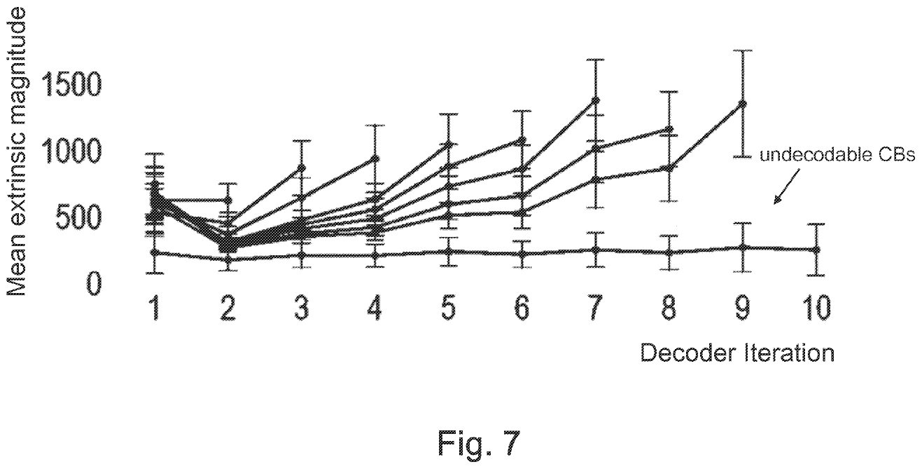

FIG. 7 illustrates the evolution of the magnitude of the average extrinsic value in CBs of different nature. Specifically, the dots/lines represent the average value across multiple CBs with different MCS (Modulation and Coding Scheme), TBS (Transport Block Size) and SNR (Signal-to-Noise Ratio). Error bars indicate the standard deviation According to the illustrated example, a CB is decodable if the decoder requires less than 10 iterations to extract data from the CB. Conversely, undecodable CBs reach the 10^{th} iteration (as shown in the bottom line in FIG. 7). This experimental result validates the approach according to embodiments of the invention disclosed herein: Decodable CBs do present patterns in mean extrinsic magnitude that are distinguishable from those for undecodable CBs, which can be used to infer the decodability of CBs.

According to an embodiment, the present invention provides a method of operating a virtualized radio access point, vRAP, that exploits extrinsic information, which propagates along every iteration in LDPC and turbo decoders, among others, to predict the decodability of CBS, when the time budget to process uplink processing tasks (PUSCH) expires. This enables to provide both reliability (as PUSCH decoding tasks have a hard time deadline and therefore do not cause head-of-line blocking as introduced earlier), yet preserve spectrum efficiency (as it becomes possible to opportunistically acknowledge data to the users while the decoder continues to process the data, instead of discarding this data and requesting the users to re-transmit).

Specifically, according to an embodiment of the invention it may be provided to extrinsic information spawning from the decoding operation at each iteration. When the time budget of DSP job n expires at time Φₙ, it may be provided to observe the state S of the decoding task being executed by each unfinished worker w processing transport blocks that have not matched CRC yet, S_{w,t}_{ₙ}_{=Φ}_{ₙ} at that time within the job tₙ=Φₙ. In this embodiment, a state may be defined as a triple S_{w}:={K, L̅ₑ̅_̅{̅₁̅}̅, L̅ₑ̅_̅{̅₂̅}̅}, wherein K∈ [symbol] denotes the number of full iterations completed so far by the decoder

$$\overline{{L}_{{e}_{ι}}} := [ \frac{1}{N} {\sum }_{b = 1}^{N} \vert {L}_{{e}_{i} , b}^{( 1 )} \vert , … , \frac{1}{N} {\sum }_{b = 1}^{N} \vert {L}_{{e}_{i} , b}^{( K )} \vert ]$$

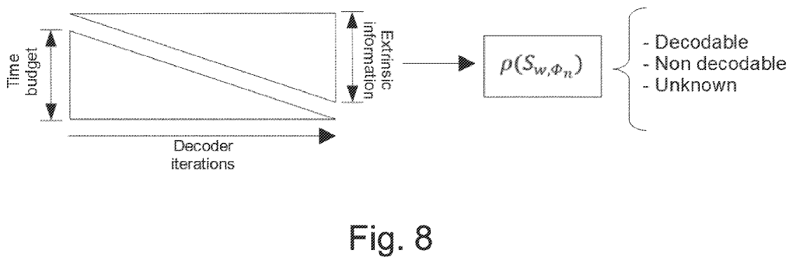

for i={1,2} is a k-dimensional vector comprised of the mean magnitude of the extrinsic LLRs at each iteration k={1, . . . , K}, where N is the length of the coded block being decoded and Lₑ_{ᵢ}_{,b} is the extrinsic LLR of bit b. Given S_{w,Φ}_{ₙ} at time Φₙ (when the time budget expires), a rule ρ(S_{w,Φ}_{ₙ})∈{DECODABLE, UNDECODABLE, UNKNOWN} may be applied to decide upon the decodability, undecodability, or uncertain decodability of the TB. This approach is schematically illustrated in FIG. 8. Early stopping criteria, commonly used in 4G and 5G by using CRC can also be used complementarily to this and others embodiments described herein. That is, if the data is successfully decoded (i.e. CRC matches) before exhausting the time budget, the transport block may be acknowledged independently of the extrinsic information.

Embodiments of the present invention primarily aim at reaching either a decodable or an undecodable decision. The former evidently is desirable because in that case it is possible that the data is sent upstream in the protocol stack and that its successful reception is acknowledged to the transmitter. The latter is also desirable because it indicates the chunk of data cannot be decoded due to poor channel conditions and the MAC scheduler has already mechanisms to adapt to this scenario.

The third possible output as mentioned above, i.e. ‘unknown’, is however an indicator of deficit of computing resources, irrespective of the quality of the channel. According to an embodiment of the present invention, this information can be used by the MAC scheduler to adjust the amount of data that the users are allowed to send in order to adapt to the availability of computing capacity.

According to an embodiment of the present invention, this can be achieved by employing, for instance, an additive-increase/multiplicative-decrease (AIMD) algorithm to the amount of uplink resources allocated to the users. Specifically, a congestion window (cwnd) may be configured to constrain the maximum amount of physical resource blocks (PRBs) allocated to all users. Then, the MAC scheduler may increase the congestion window by M PRBs every code block that is declared decodable or undecodable in DSP job n. Conversely, the congestion window may multiplicatively decrease by a backoff factor U for every code block with unknown decodability, that is, cwnd⁽ⁿ⁺¹⁾=(cwnd⁽ⁿ⁾+Σₘ M)U^{u}, where m is the number code blocks declared decodable or undecodable and u is the number of code blocks with unknown decodability.

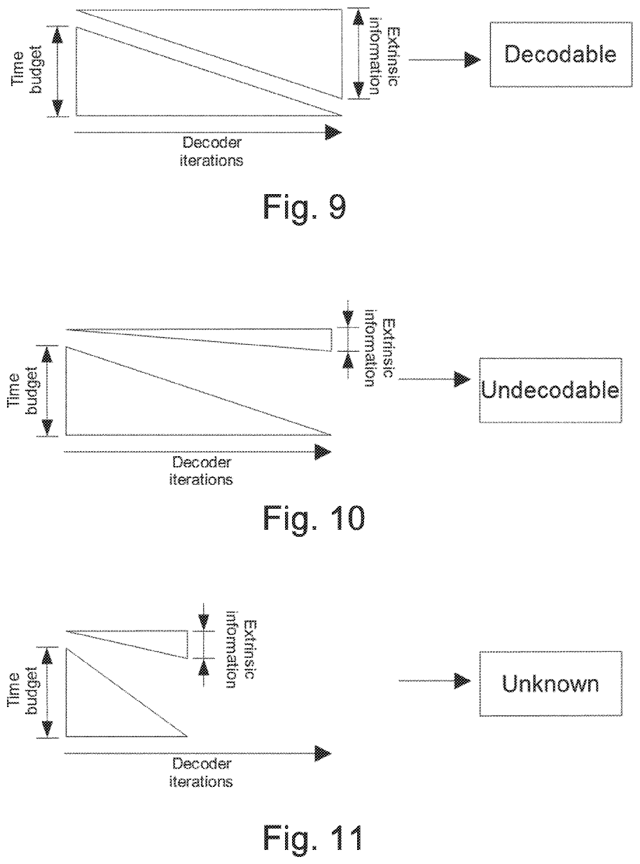

According to further embodiments of the invention, the rule ρ(S_{w,Φ}_{ₙ}) may be defined based upon the following observations from FIG. 7, wherein standard classifiers can be used to implement the respective steps:
1. If the magnitude of the extrinsic information after the last decoder iteration is sufficiently large (e.g., exceeding a first predefined threshold) or if the trend of the magnitude of extrinsic information over iterations is sufficiently large (e.g., exceeding a second predefined threshold), it may be inferred that the code block is decodable. This scenario is schematically illustrated in FIG. 9.
2. Otherwise, if the total number of iterations is sufficiently high (e.g., exceeding a third predefined threshold), it may be inferred that the code block is not decodable and the user may be requested for retransmission. This scenario is schematically illustrated in FIG. 10.
3. Otherwise, decodability of the code block cannot be inferred and the user may be requested for retransmission. This scenario is schematically illustrated in FIG. 11. In this case, the information can be used by the MAC scheduler to adjust the amount of data that the users are allowed to send in order to adapt to the availability of computing capacity, as already described above.

It should be noted that a high rate of false positives or false negatives when inferring the decodability of data may lead to poor performance. However, as will be appreciated by those skilled in the art, this issue can be fixed by appropriately building the classifier and by using conservative predictions.

To summarize, embodiments of the present invention include the following important aspects:
1) Exploiting extrinsic information in belief propagation algorithms used in data decoders such as turbo decoders or LDPC decoders used in 4G and 5G networks to infer the decodability of data upon exhausting a computing time budget.
2) Sending acknowledgment (ACK) to a user based on the decodability inferred in the previous step while the decoder continues processing the data in parallel.
3) Using information about the decodability of data in step (1) to adapt the rate at which uplink data is scheduled to the availability of computing capacity.

Many modifications and other embodiments of the invention set forth herein will come to mind to the one skilled in the art to which the invention pertains having the benefit of the teachings presented in the foregoing description and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A method of operating a virtualized radio access point, (vRAP), the method comprising:
encoding/decoding transport blocks (TBs) by using iterative codes that exchange extrinsic information in each iteration; and
exploiting the exchanged extrinsic information to infer information about decodability of the data of the TBs.

2. The method according to claim 1, wherein the iterative codes used for encoding/decoding transport blocks (TBs) comprise turbo codes and/or LDPC, codes employing iterative belief propagation algorithms.

3. The method according to claim 1, wherein inferring information about the decodability of the data of the TBs comprises determining, based on an analysis of the exchanged extrinsic information, a decodability status of the data as either ‘decodable’, ‘undecodable’ or ‘unknown’.

4. The method according to claim 1, wherein inferring information about the decodability of the data of the TBs is performed when a deadline for computing signals to send feedback to respective users expires.

5. The method according to claim 1, further comprising:
determining a magnitude of the exchanged extrinsic information after a last decoding iteration; and
inferring that respective data are decodable based on a determining that the magnitude exceeds a first configurable threshold.

6. The method according to claim 1, further comprising:
determining a trend of a magnitude of the extrinsic information over the decoding iterations; and
inferring that respective data are decodable based on a determining that the trend exceeds a second configurable threshold.

7. The method according to claim 1, further comprising:
based on a determining that user data are determined to be decodable, sending an acknowledgement (ACK) to a user; and
continuing decoding the user data in parallel.

8. The method according to claim 1, further comprising:
based on a determining that user data are undecodable or based on a determining that the inferred information about the decodability does not permit to determine whether user data is decodable or not, stopping decoding the data and computing signals to request a user to retransmit the data.

9. The method according to claim 1, further comprising:
based on a determining that user data are decodable, increasing an amount of data a scheduler is allowed to allocate to users, and/or
based on a determining that user data are undecodable or based on a determining that the inferred information about the decodability does not permit to determine whether user data is decodable or not, decreasing the amount of data the scheduler is allowed to allocate to users.

10. The method according to claim 1, further comprising:
using the inferred information about the decodability of data to adapt a rate at which uplink data is scheduled to the availability of a computing capacity of the vRAP's.

11. A virtualized radio access point (vRAP), the system comprising:
an encoder/decoder configured to encode/decode transport blocks (TBs) by using iterative codes that exchange extrinsic information in each iteration; and
a digital signal processor (DSP) pipeline configured to infer information about the decodability of the data of the TBs by exploiting the exchanged extrinsic information.

12. The virtualized radio access point according to claim 11, wherein the encoder/decoder is a turbo encoder/decoder configured to operate based on two interleaved convolutional codes; or
wherein the encoder/decoder is configured to use low-density parity check (LDPC) codes.

13. The virtualized radio access point according to claim 12, wherein the turbo decoder is configured to execute a belief propagation algorithm that is implemented by two convolutional decoders that exchange extrinsic log-likelihood ratios (LLRs) iteratively, wherein the LLRs represent a reliability information computed for a received sequence of systematic bits and parity bits generated by the corresponding turbo encoder.

14. The virtualized radio access point according to claim 11, wherein the DSP pipeline is configured to determine, based on an analysis of the exchanged extrinsic information, a decodability status of the data as either ‘decodable’, ‘undecodable’ or ‘unknown’.

15. The virtualized radio access point according to claim 11, further comprising a scheduler configured to use the inferred information about the decodability of data to adapt a rate at which uplink data is scheduled to an availability of a computing capacity of the vRAP.
